(19) United States
(12) Patent Application Publication
(10) Pub. No.: US 2008/0099765 A1
(43) Pub. Date: May 1, 2008

(54) THIN FILM TRANSISTOR SUBSTRATE AND FABRICATING METHOD THEREOF

(75) Inventors: Do-Hyun KIM, Seoul (KR); Je-Hun LEE, Seoul (KR); Chang-Oh JEONG, Suwon-si (KR)

Correspondence Address: CANTOR COLBURN, LLP, 20 Church Street, 22nd Floor, Hartford, CT, 06103, US

(73) Assignee: SAMSUNG ELECTRONICS CO., LTD.,, Suwon-si (KR)

(21) Appl. No.: 11/923,914

(22) Filed: Oct. 25, 2007

(30) Foreign Application Priority Data
Oct. 25, 2006 (KR) 1020060104176

(51) Int. Cl. H01L 29/04; H01L 21/336

(52) U.S. Cl. 257/59; 438/158; 257/E29.003; 257/E21.001

(57) ABSTRACT

A thin film transistor substrate and fabricating method thereof, the thin film transistor substrate including a substrate, a gate line and a gate electrode, each including a metal adhesion layer and a Cu alloy layer disposed on the substrate, an active layer and an ohmic contact layer disposed over the gate electrode, a gate insulating layer disposed between the gate electrode and the active and ohmic contact layers, source and drain electrodes disposed on the ohmic contact layer, and a data line connected to the source electrode.

This application claims priority to Korean Patent Application No. 2006-0104176, filed on Oct. 25, 2006, and all the benefits accruing therefrom under 35 U.S.C. §119, the contents of which in its entirety are herein incorporated by reference.

### BACKGROUND OF THE INVENTION

1. Field of the Invention

The present invention relates to a thin film transistor (“TFT”) substrate and fabricating method thereof.

2. Description of the Related Art

An active matrix liquid crystal display has a good response characteristic and an advantage suitable for a large number of pixels. The active matrix liquid crystal display is able to realize high resolution and large scale of a display device as good as or better than a display device using a cathode ray tube.

In fabricating a TFT substrate used for an active matrix liquid crystal display, a plurality of mask processes is performed. The mask process includes the process including the step of forming a photoresist pattern using a mask having an exposure part and a non-exposure part to form a specific pattern on a substrate, and the step of forming a microscopic pattern on the substrate using the photoresist pattern.

As a disadvantage, the mask process requires a high process cost and may bring environmental contamination attributed to a relatively large quantity of chemicals used for the process. As a further disadvantage, the mask process delays a process time, thereby adding costs.

Efforts have been made to reduce the number of mask processes, thereby developing a 4-mask or 3-mask process capable of replacing the conventional 5 to 7 mask processes by 4 or 3 mask processes. In the 4- or 3-mask process, both an active layer and source and drain electrodes are simultaneously patterned using one mask.

FIG. 1 is a plan view of a TFT substrate according to the related art. In the related art, a gate pattern including a gate line 5 and a gate electrode 6 or a source/drain pattern including a source electrode 3 and a drain electrode 4 is formed of pure copper. In case of forming the gate or source/drain pattern of the pure copper, wet etching is used. An active layer is exposed out of a source/drain line. An active layer 2 always remains under the source electrode 3 and the drain electrode 4 in the 4-mask process or 3-mask process. Since the source/drain electrode pattern formed of copper and the active layer 2 are etched by wet etching, an edge of the active layer 2 remaining under the source and drain electrodes 3 and 4, is not etched and remains to be exposed out of the source and drain electrodes 3 and 4.

As a disadvantage, the active layer 2 exposed out of the source and drain electrodes 3 and 4 reduces an opening ratio and causes a deterioration or failure of the display device, such as waterfall noise or afterimage. Moreover, the copper of the gate pattern or source/drain pattern diffuses into silicon of a gate insulating layer (not shown) or a passivation layer (not shown).

### BRIEF SUMMARY OF THE INVENTION

An exemplary embodiment provides a TFT substrate and fabricating method thereof, in which dry etching is applicable in a manner of forming a gate pattern or a source/drain pattern of a Cu alloy layer and in which an active layer is formed within a source/drain pattern only.

In an exemplary embodiment, a TFT substrate includes a substrate, a gate line and a gate electrode, each including a metal adhesion layer and a Cu alloy layer disposed on the substrate, an active layer and an ohmic contact layer disposed over the gate electrode, a gate insulating layer disposed between the gate electrode and the active and ohmic contact layers, source and drain electrodes disposed on the ohmic contact layer, and a data line connected to the source electrode.

In an exemplary embodiment, a TFT substrate includes a substrate, a gate line and a gate electrode, each including a first metal adhesion layer and a first Cu alloy layer disposed on the substrate, an active layer and an ohmic contact layer disposed over the gate electrode, a gate insulating layer disposed between the gate electrode and the active and ohmic contact layers, source and drain electrodes disposed on the ohmic contact layer, each including a second metal adhesion layer and a second Cu alloy layer, and a data line connected to the source electrode, the data line including the second metal adhesion layer and the second Cu alloy layer.

In an exemplary embodiment, a method of fabricating a TFT substrate includes forming a gate line and a gate electrode, each including a metal adhesion layer and a Cu alloy layer, on a substrate, sequentially stacking a gate insulating layer, an active layer, and an ohmic contact layer on the gate line and the gate electrode, forming source and drain electrodes and a data line, the forming source and drain electrodes and a data line including stacking a source/drain layer on the ohmic contact layer and patterning the source/drain layer, and sequentially patterning the active layer and the ohmic contact layer.

In an exemplary embodiment, a method of fabricating a TFT substrate includes forming a gate line and a gate electrode, the forming a gate line and a gate electrode including sequentially depositing a first metal adhesion layer and a first Cu alloy layer on a substrate and patterning the first metal adhesion layer and the first Cu alloy layer, sequentially stacking a gate insulating layer, an active layer, and an ohmic contact layer on the gate line and the gate electrode, forming source and drain electrodes and a data line, the forming source and drain electrodes and a data line including sequentially depositing a second metal adhesion layer and a second Cu alloy layer on the ohmic contact layer and patterning the second metal adhesion layer and the second Cu alloy layer, and sequentially patterning the active layer and the ohmic contact layer.

### BRIEF DESCRIPTION OF THE DRAWINGS

The above and other aspects, features and advantages of the present invention will become more apparent from the following detailed description when taken in conjunction with the accompanying drawings in which:

FIG. 1 is a plan view of a TFT substrate according to a prior art;

FIG. 2 is a plan view of an exemplary embodiment of a TFT substrate according to the present invention;

FIG. 3 is a cross-sectional view of the TFT substrate taken along line I-I′ in FIG. 2; and

FIGS. 4A, 4B, 5A, 5B, 5C, 6, 7A, 7B, 8A, 8B, 9A, and 9B are plan views and cross-sectional views to explain an exemplary embodiment of a method of fabricating a TFT substrate according to the present invention.

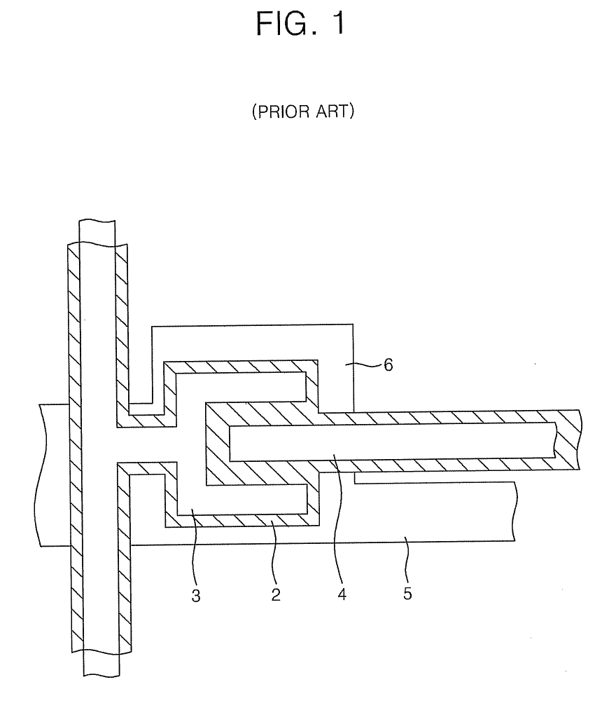

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “lower”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “beneath” other elements or features would then be oriented “above” the other elements or features. Thus, the exemplary term “beneath” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

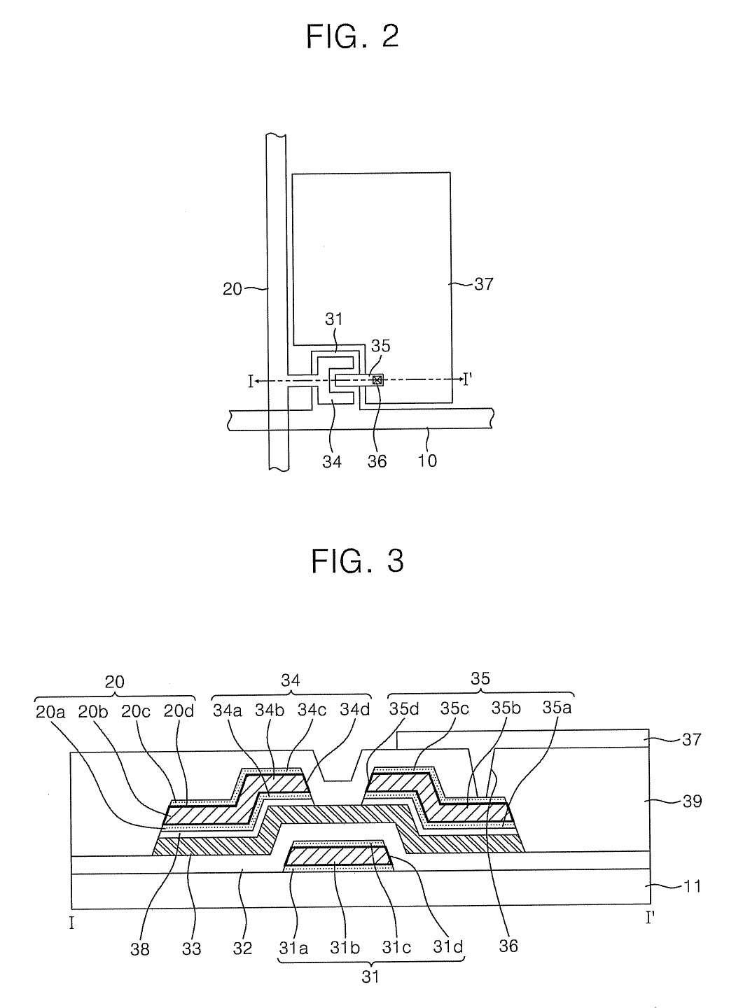

FIG. 2 is a plan view of an exemplary embodiment of a TFT substrate according to the present invention, and FIG. 3 is a cross-sectional view of the TFT substrate taken along line I-I′ in FIG. 2.

Referring to FIG. 2 and FIG. 3, a TFT substrate includes a substrate 11, a gate line 10, a gate electrode 31, a gate insulating layer 32, an active layer 33, an ohmic contact layer 38, a source electrode 34, a drain electrode 35, a data line 20, a passivation layer 39, and a pixel electrode 37.

The gate electrode 31, the gate insulating layer 32, the active layer 33, the ohmic contact layer 38, the source electrode 34, and the drain electrode 35 constitute a thin film transistor (“TFT”). The TFT enables the pixel electrode 37 to be charged with a pixel signal supplied to the data line 20 in response to a scan signal supplied to the gate line 10. In the exemplary embodiment, the gate electrode 31, as shown in FIG. 2, is formed in one body with the gate line 10 and the source electrode 34 is formed in one body with the data line 20.

The active layer 33 and a gap between portions of the source electrode 34 and drain electrode 35, forms a channel between the source and drain electrodes 34 and 35. The ohmic contact layer 38 configures an ohmic contact between the source and drain electrodes 34 and 35 and the active layer 33 to reduce a work function difference between the source and drain electrodes 34 and 35 and the active layer 33. The drain electrode 35 is connected to the pixel electrode 37 to supply a pixel voltage to the pixel electrode 37. In the exemplary embodiment, the pixel electrode 37 may be formed across a whole surface of a pixel area and forms an electric field with a separately provided common electrode disposed on a facing substrate (not shown).

The gate electrode 31 of the present embodiment, as shown in FIG. 3, includes a metal adhesion layer 31a and a Cu alloy layer 31b stacked (e.g., disposed directly) on the metal adhesion layer 31a. In an exemplary embodiment, when the gate electrode 31 is formed of a Cu alloy, dry etching may be applicable thereto. Advantageously, chemical resistance is enhanced compared to the case of using pure Cu. Since attachment power of the Cu alloy is inferior to that of the pure Cu, the metal adhesion layer 31a is provided under the Cu alloy layer 31b, as illustrated in FIG. 3.

The Cu alloy layer 31b according to the present embodiment is formed of an alloy including Cu and a Cu non-solid solution element. In an exemplary embodiment, the Cu non-solid solution element includes an element that is not mutually soluble with Cu in a solid or liquid phase. The Cu non-solid solution element does not form a chemical compound or an alloy by a general process. In one exemplary embodiment, the Cu non-solid solution element includes at least one selected from the group consisting of molybdenum (Mo), niobium (Nb), vanadium (V), cupper (Co), silver (Ag), chrome (Cr), tungsten (W), tantalum (Ta), zirconium (Zr), and thallium (Tl).

The metal adhesion layer 31a is formed between the Cu alloy layer 31b and the substrate 11 to enhance adhesion between the Cu alloy layer 31b and the substrate 11. In the present embodiment, the metal adhesion layer 31a may include a Mo layer and/or a Mo alloy layer. In an exemplary embodiment, the Mo or Mo alloy layer may be removed, such as by dry etching.

In the present embodiment, the Mo alloy layer may be formed by alloying Mo with a low surface energy metal element having surface energy lower than that of Mo. In an exemplary embodiment, the low surface energy metal element includes a metal element of which surface energy is lower than that of Mo. The metal element having the low surface energy is advantageous in diffusing into a Cu alloy layer with relative ease. In one exemplary embodiment, the low surface energy metal element includes at least one selected from the group consisting of zinc (Zn), cobalt (Co), cerium (Ce), neodymium (Nd), magnesium (Mg), titanium (Ti), tantalum (Ta), zirconium (Zr), and vanadium (V).

In an exemplary embodiment including the structure of stacking the metal adhesion layer 31a and the Cu alloy layer 31b, when heat over about 200° C. is applied thereto, metal of the metal adhesion layer 31a diffuses to form a diffusion layer 31d on a surface of the Cu alloy layer 31b. The diffusion layer 31d enhances the adhesion between the Cu alloy layer 31b and the metal adhesion layer 31a and prevents the Cu exposed out of a side part of the Cu alloy layer 31b from reacting with the gate insulating layer 32.

The diffusion layer 31d is naturally formed when heat over about 200° C. is applied thereto. Therefore, a thermal process may be separately carried out. Instead, when chemical vapor deposition (“CVD”) is used in forming the gate insulating layer 32 on the Cu alloy layer 31b, heat is naturally applied to form the diffusion layer 31d without a separate thermal process.

A top metal layer 31c is preferably formed on the Cu alloy layer 31b. The top metal layer 31c is formed between the Cu alloy layer 31b of the gate electrode 31 and the gate insulating layer 32 to prevent the diffusion between the Cu alloy layer 31b and the gate insulating layer 32.

The gate insulating layer 32 deposited on the Cu alloy layer 31b may be formed of an inorganic insulating material, such as silicon oxide (SiOₓ) or silicon nitride (SiNₓ). In an exemplary embodiment, the inorganic insulating material may be deposited, such as by CVD. In one exemplary embodiment, such as using high temperature CVD, a temperature of a substrate rises over about 370° C. in the course of the corresponding process. Silicon of the gate insulating layer 32 may diffuse into the Cu alloy layer 31b. To prevent the diffusing of the gate insulating layer 32 into the Cu alloy layer 31b, the top metal layer 31c is formed on the Cu alloy layer 31b. In another exemplary embodiment, in case of using low temperature CVD, the top metal layer 31c may not be necessary.

In the present embodiment, the top metal layer 31c is formed of Mo or a Mo alloy. The Mo alloy layer is substantially identical to that used for a gate pattern, and thus a repetitive description is omitted.

In the illustrated embodiment, the gate line 10 shown in FIG. 2, is formed in one body with the gate electrode 31 and has the substantially same (layered) structure of the gate electrode 31.

As mentioned in the foregoing description, although the gate pattern including the gate line 10 and the gate electrode 31 is formed with a triple layer of Mo/Cu alloy/Mo, the triple layer may be patterned, such as by dry etching. Advantageously, the corresponding process for forming the triple layer of the gate pattern is simplified. In one embodiment, a specific taper shape of the gate pattern may be formed, such as by adjusting thickness of each layer, such as illustrated in FIG. 3.

Referring again to FIG. 3, the data line 20 includes a metal adhesion layer 20a and a Cu alloy layer 20b. The source electrode 34 includes a metal adhesion layer 34a and a Cu alloy layer 34b. The drain electrode 35 includes a metal adhesion layer 35a and a Cu alloy layer 35b. In one exemplary embodiment, the Cu alloy layers 20b, 34b and 35b are formed, such as by alloying Cu with a Cu non-solid solution element. The metal adhesion layers 20a, 34a and 35a may be formed of Mo or a Mo alloy. The Cu alloy layer and the metal adhesion layer are substantially identical to those of the gate pattern, and thus a detail description is omitted.

In an exemplary embodiment including the structure of sequentially stacking the metal adhesion layers 20a, 34a and 35a and the Cu alloy layers 20b, 34b and 35b, respectively, when heat is applied thereto, metal of the metal adhesion layers 20a, 34a and 35a diffuses to form diffusion layers 20d, 34d and 35d on a surface of the Cu alloy layers 20b, 34b and 35b.

As in the illustrated embodiment, top metal layers 20c, 34c and 35c are formed between the Cu alloy layers 20b, 34b and 35b and the passivation layer 39 to reduce or effectively prevent the diffusion between the Cu alloy layers 20b, 34b and 35b and the passivation layer 39.

In an exemplary embodiment, although each of the data line 20 and the source and drain electrodes 34 and 35 includes the triple layer having the metal adhesion layers 20a, 34a and 35a, the Cu alloy layers 20b, 34b and 35b, and the top metal layers 20c, 34c and 35c, respectively, the triple layer may be etched, such as by wet or dry etching. Advantageously, by removing the source/drain metal together with the active layer in the 4- or 3-mask process by dry or wet etching, the TFT substrate may be obtained, of which the active layer is not exposed out of the source and drain electrodes 34 and 35.

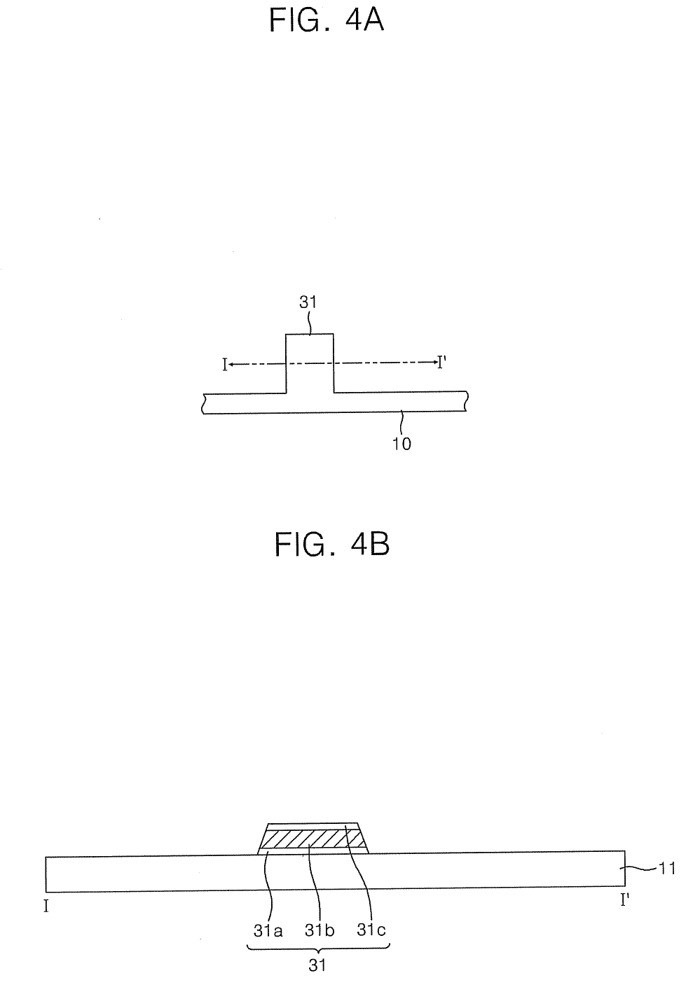

An exemplary embodiment of a method of fabricating the TFT substrate according to the present invention will now be explained with reference to FIGS. 4A to 9B.

FIG. 4A and FIG. 4B are a plan view and a cross-sectional view, respectively, illustrating an exemplary embodiment of a first mask process in a TFT substrate fabricating method according to the present invention.

In the first mask process, a gate metal pattern of the triple-layer structure including the metal adhesion layer 31a, the Cu alloy layer 31b, and the top metal layer 31c is formed on the lower substrate 11. In the illustrated embodiment, the gate metal pattern includes the gate line 10 and the gate electrode 31.

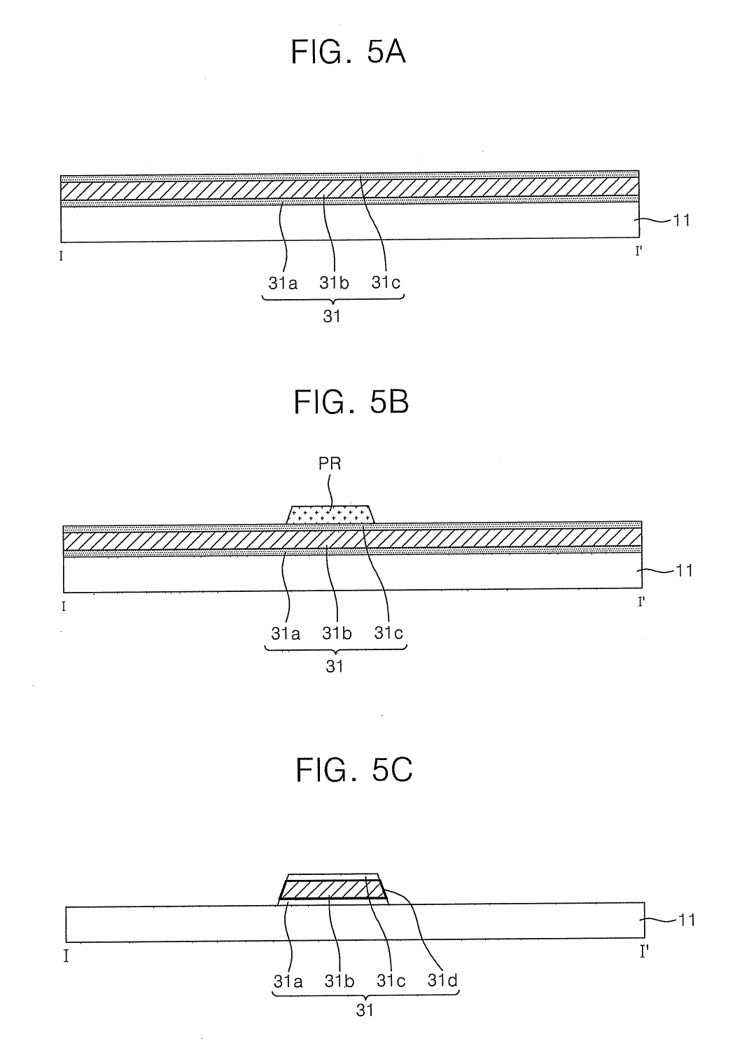

FIGS. 5A to 5C are cross-sectional views illustrating the first mask process in detail.

Referring to FIG. 5A, the metal adhesion layer 31a, the Cu alloy layer 31b, and the top metal layer 31c are sequentially deposited on an upper surface of the substrate 11. In an exemplary embodiment, the top metal layer 31c may be omitted. The metal adhesion layer 31a, the Cu alloy layer 31b, and the top metal layer 31c may be deposited, such as by sputtering. For the deposition of the metal adhesion layer 31a and the top metal layer 31c, a thin film is deposited using a sputtering target including Mo or a Mo alloy. For the deposition of the Cu alloy layer 31b, a thin film is deposited using a sputtering target including a Cu alloy.

After completion of the deposition of the triple layer of the gate pattern, a photoresist pattern PR, as shown in FIG. 5B, is formed on a part of the triple layer on which a gate electrode 31 is to be formed, such as by photolithography.

Referring to FIG. 5C, the triple layer except for the part covered with the photoresist pattern PR is removed, such as by an etching process. The photoresist pattern PR is subsequently removed, such as by a striping process, to form the gate electrode 31.

In an exemplary embodiment, the metal adhesion layer 31a, the Cu alloy layer 31b, and the top metal layer 31c may be etched, such as by a single dry or wet etching process. When heat over about 200° C. is applied, metal of the metal adhesion layer 31a may diffuse to form the diffusion layer 31d on a surface of the Cu alloy layer 31b.

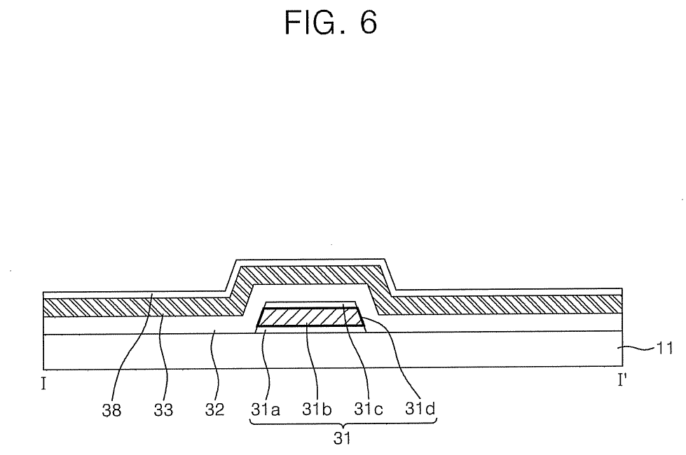

Referring to FIG. 6, the gate insulating layer 32, the active layer 33, and the ohmic contact layer 38 are sequentially stacked (e.g., disposed) on the substrate 11 on which the gate electrode 31 has been previously formed. In one exemplary embodiment, the gate insulating layer 32, the active layer 33, and the ohmic contact layer 38 may be formed by plasma enhanced chemical vapor deposition (“PECVD”). The gate insulating layer 32 may be formed of the inorganic material such as SiOₓ or SiNₓ. The active layer 33 may be formed of amorphous silicon or polysilicon. The ohmic contact layer 38 may be formed of doped amorphous silicon or doped polysilicon.

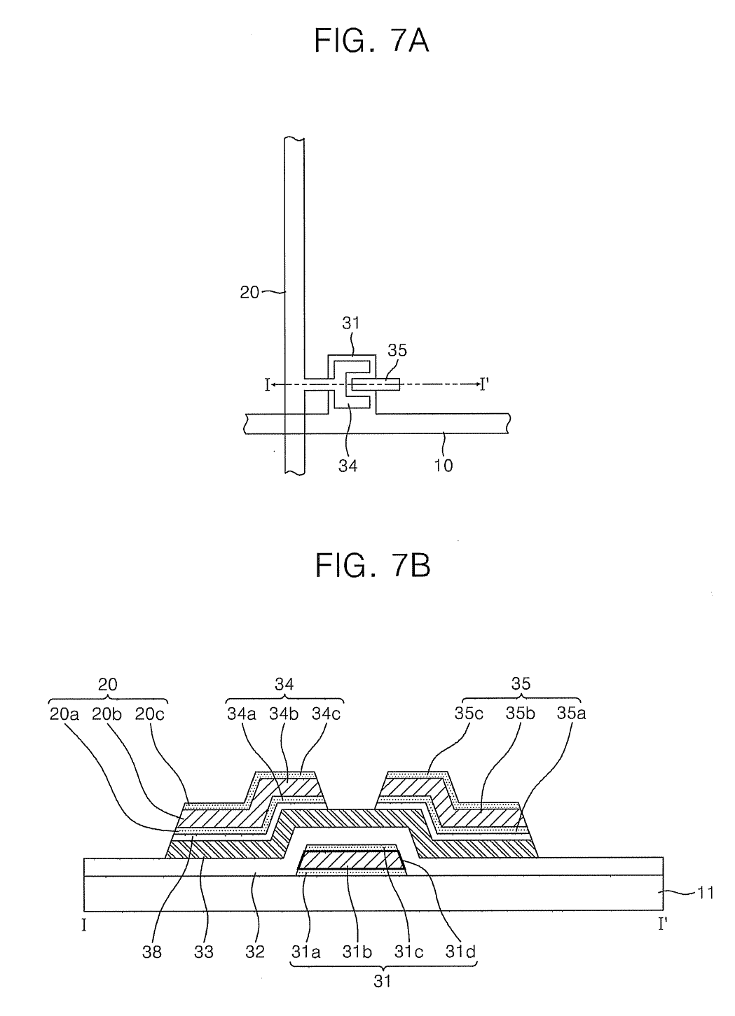

FIG. 7A and FIG. 7B are a plan view and a cross-sectional view, respectively, illustrating an exemplary embodiment of a second mask process in the TFT substrate fabricating method according to the present invention.

After the gate insulating layer 32 has been formed on the substrate 11 including the gate metal pattern, a source/drain metal pattern including the data line 20, the source electrode 34, and the drain electrode 35, and a semiconductor pattern including the active layer 33 and the ohmic contact layer 38 overlapped under the source/drain pattern are formed on the gate insulating layer 32 in the second mask process. In the illustrated embodiment, the semiconductor pattern and the source/drain metal pattern are formed by a single mask process, such as using a slit mask or a half-tone mask.

The gate insulating layer 32, the active layer 33, an impurity (n⁺ or p⁺) doped ohmic contact layer 38, and the source/drain metal layer are sequentially formed on the substrate 11 including the gate metal pattern. In the illustrated embodiment, the source/drain metal layer has a triple-layer structure of Mo/Cu alloy/Mo, substantially the same as the gate metal layer. The source/drain metal layer is formed by the substantially same method of forming the gate metal layer. In the illustrated embodiment, after photoresist has been coated on the source/drain metal layer, exposure and development are carried out on the photoresist, such as by a photolithography process and/or using a slit mask, thereby forming a photoresist pattern having a step difference.

As in the illustrated embodiment, the source/drain metal layer is patterned by an etching process using the photoresist pattern having the step difference. Advantageously, the source/drain metal pattern including the source and drain electrodes 34 and 35, and the data line 20 is formed. Additionally, a semiconductor pattern including the active layer 33 and the ohmic contact layer 38 is formed under the source/drain metal pattern. In an exemplary embodiment, the source electrode 34 and the drain electrode 35 are connected to each other in the source/drain metal pattern.

The photoresist pattern is removed in part, such as by O₂ plasma ashing. A relatively thick portion of the photoresist pattern is reduced in thickness, and a relatively thin portion of the photoresist pattern is substantially completely removed. The exposed source/drain metal layer and the ohmic contact layer 34 beneath the exposed source/drain metal layer are removed, such as by an etching process using the ashed thick photoresist pattern. The source and drain electrodes 34 and 35 are essentially disconnected from each other, and the active layer 33 is exposed, as illustrated in FIG. 7B.

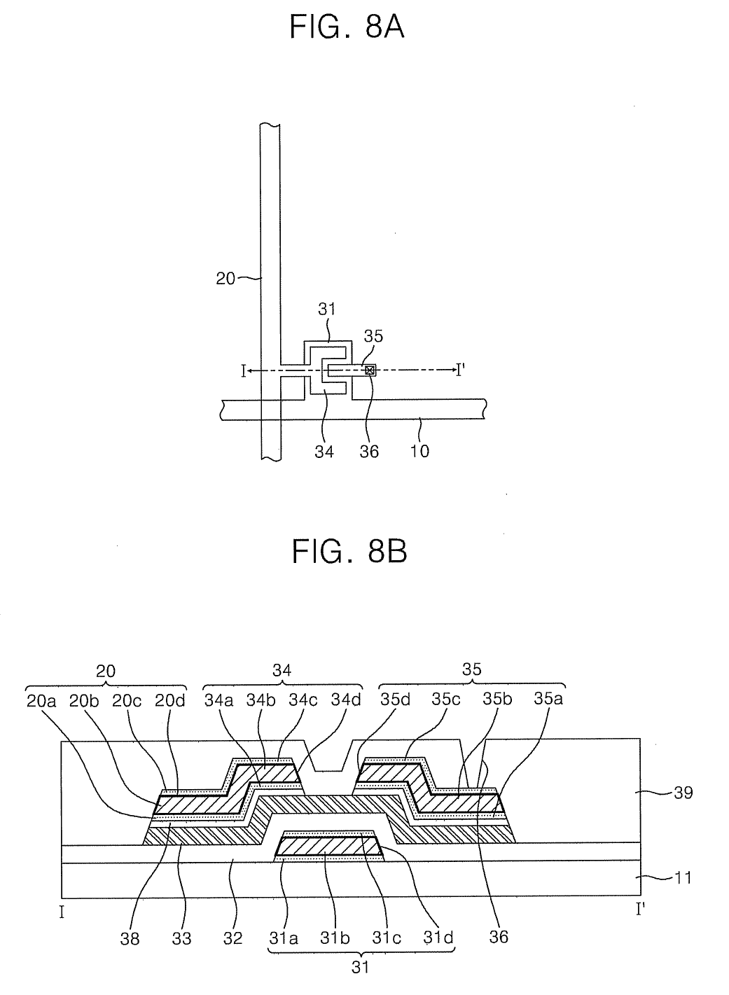

FIG. 8A and FIG. 8B are a plan view and a cross-sectional view, respectively, illustrating an exemplary embodiment of a third mask process in the TFT substrate fabricating method according to the present invention.

The passivation layer 39 including a contact hole 36 is formed in the third mask process. In an exemplary embodiment, the passivation layer 39 may be formed on the gate insulating layer 32 provided with the source/drain metal pattern, such as by using a PECVD, spin coating, or spinless coating technique. The passivation layer 39 may be formed of the inorganic insulating material of the gate insulating layer 32 formed by a CVD or PECVD technique. Alternatively, the passivation layer 39 may be formed of an organic insulating material, such as acryl based organic compound, benzocyclobutene (BCB), or perfluorocyclobutane (PFCB). Alternatively, the passivation layer 39 may be formed of a double structure including the inorganic insulating material and the organic insulating material.

After photoresist has been coated on the passivation layer 39, exposure and development are carried out on the photoresist to form a photoresist pattern on a part on which the passivation layer 39 is to be formed. The passivation layer 39 is patterned, such as by an etching process using the photoresist pattern to form the contact hole 36, as shown in FIG. 8B, thereby exposing a portion of the drain electrode 35.

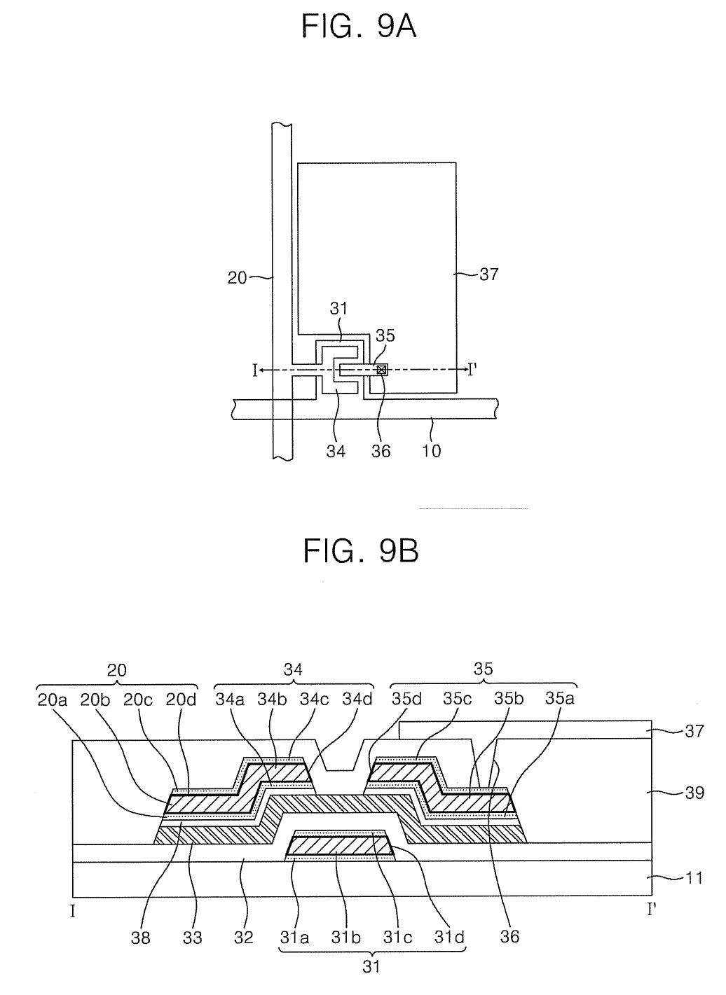

FIG. 9A and FIG. 9B are a plan view and a cross-sectional view, respectively, illustrating an exemplary embodiment of a fourth mask process in the TFT substrate fabricating method according to the present invention.

The pixel electrode 37 is formed on the passivation layer 39 in the fourth mask process. A transparent conductive layer is formed on a whole surface of the substrate 11, such as by deposition including sputtering. In one exemplary embodiment, the transparent conductive layer may be formed of indium tin oxide (ITO), tin oxide (TO), indium zinc oxide (IZO), tin dioxide (SnO₂), or amorphous-indium tin oxide (a-ITO). The transparent conductive layer is then patterned using the contact hole 36 to form the pixel electrode 37 connected to the drain electrode 35.

As in the illustrated embodiments, the present invention provides the following effects or advantages.

Firstly, the gate pattern and the source/drain metal pattern are formed of a Cu alloy, thereby enabling a process including dry etching. Secondly, the source/drain metal pattern and an active pattern may be provided by dry or wet etching using a single mask. Thirdly, exposure out of the source/drain metal pattern of an active layer may be reduced or effectively prevented.

While the present invention has been shown and described with reference to a certain exemplary embodiments thereof, it will be understood by those skilled in the art that various changes in form and details may be made therein without departing from the spirit and scope of the present invention as defined by the appended claims.

What is claimed is:

1. A thin film transistor substrate comprising:
a substrate;
a gate line and a gate electrode, each including a metal adhesion layer and a Cu alloy layer disposed on the substrate;
an active layer and an ohmic contact layer disposed over the gate electrode;
a gate insulation layer disposed between the gate electrode, and the active and ohmic contact layers;
source and drain electrodes disposed on the ohmic contact layer; and
a data line connected to the source electrode.

2. The thin film transistor substrate of claim 1, wherein the Cu alloy layer includes alloyed Cu and a Cu non-solid solution element.

3. The thin film transistor substrate of claim 2, wherein the Cu non-solid solution element comprises at least one selected from the group consisting of Mo, Nb, V, Co, Ag, Cr, W, Ta, Zr, Tl, and a combination including at least one of the foregoing.

4. The thin film transistor substrate of claim 3, wherein the metal adhesion layer comprises a Mo layer or a Mo alloy layer.

5. The thin film transistor substrate of claim 4, wherein the Mo alloy layer includes alloyed Mo and a low surface energy metal element having surface energy lower than that of the Mo.

6. The thin film transistor substrate of claim 5, wherein the low surface energy metal element comprises at least one selected from the group consisting of Zn, Co, Ce, Nd, Mg, Ti, Ta, Zr, V, and a combination including at least one of the foregoing.

7. The thin film transistor substrate of claim 4, further comprising a top metal layer between the gate electrode and the gate insulating layer, the top metal layer preventing diffusion between the Cu alloy layer and the gate insulating layer.

8. The thin film transistor substrate of claim 7, wherein the top metal layer comprises a Mo layer or a Mo alloy layer.

9. The thin film transistor substrate of claim 8, wherein the Mo alloy layer includes alloyed Mo and a low surface energy metal element having surface energy lower than that of the Mo.

10. The thin film transistor substrate of claim 9, wherein the low surface energy metal element comprises at least one selected from the group consisting of Zn, Co, Ce, Nd, Mg, Ti, Ta, Zr, V, and a combination including at least one of the foregoing.

11. The thin film transistor substrate of claim 4, further comprising a diffusion layer disposed on an surface of the Cu alloy layer.

12. A thin film transistor substrate comprising:
a substrate;
a gate line and a gate electrode, each including a first metal adhesion layer and a first Cu alloy layer disposed on the substrate;
an active layer and an ohmic contact layer disposed over the gate electrode;
a gate insulating layer disposed between the gate electrode and the active and ohmic contact layers;
source and drain electrodes disposed on the ohmic contact layer, each including a second metal adhesion layer and a second Cu alloy layer; and
a data line connected to the source electrode, the data line including the second metal adhesion layer and the second Cu alloy layer.

13. The thin film transistor substrate of claim 12, wherein the second Cu alloy layer includes alloyed Cu and a Cu non-solid solution element.

14. The thin film transistor substrate of claim 13, wherein the Cu non-solid solution element comprises at least one selected from the group consisting of Mo, Nb, V, Co, Ag, Cr, W, Ta, Zr, Tl, and a combination including at least one of the foregoing.

15. The thin film transistor substrate of claim 13, wherein the second metal adhesion layer comprises a Mo layer or a Mo alloy layer.

16. The thin film transistor substrate of claim 15, wherein the Mo alloy layer includes alloyed Mo and a low surface energy metal element having surface energy lower than that of the Mo.

17. The thin film transistor substrate of claim 16, wherein the low surface energy metal element comprises at least one selected from the group consisting of Zn, Co, Ce, Nd, Mg, Ti, Ta, Zr, V, and a combination including at least one of the foregoing.

18. The thin film transistor substrate of claim 15, further comprising:
a top metal layer disposed on the second Cu alloy layer; and
a passivation layer disposed on the top metal layer,
wherein the top metal layer prevents diffusion between the second Cu alloy layer and the passivation layer.

19. The thin film transistor substrate of claim 18, wherein the top metal layer comprises a Mo layer or a Mo alloy layer.

20. The thin film transistor substrate of claim 19, wherein the Mo alloy layer includes alloyed Mo and a low surface energy metal element having surface energy lower than that of the Mo.

21. The thin film transistor substrate of claim 20, wherein the low surface energy metal element comprises at least one selected from the group consisting of Zn, Co, Ce, Nd, Mg, Ti, Ta, Zr, V, and a combination including at least one of the foregoing.

22. The thin film transistor substrate of claim 15, further comprising a pixel electrode disposed on the passivation layer and connected to the drain electrode via a contact hole, wherein the passivation layer includes the contact hole exposing the drain electrode.

23. A method of fabricating a thin film transistor substrate, the method comprising:
forming a gate line and a gate electrode, each including a metal adhesion layer and a Cu alloy layer, on a substrate;
sequentially stacking a gate insulating layer, an active layer, and an ohmic contact layer on the gate line and the gate electrode;
forming source and drain electrodes and a data line, the forming source and drain electrodes and a data line including stacking a source/drain layer on the ohmic contact layer and patterning the source/drain layer; and
sequentially patterning the active layer and the ohmic contact layer.

24. The method of claim 23, wherein the forming a gate line and a gate electrode comprises:
sequentially depositing the metal adhesion layer and the Cu alloy layer; and
patterning the metal adhesion layer and the Cu alloy layer.

25. The method of claim 24, wherein the patterning the metal adhesion layer and the Cu alloy layer includes etching the metal adhesion layer and the Cu alloy layer with a dry etching process.

26. The method of claim 25, further comprising forming a top metal layer on the Cu alloy layer.

27. A method of fabricating a thin film transistor substrate, the method comprising:
forming a gate line and a gate electrode, the forming a gate line and a gate electrode including sequentially depositing a first metal adhesion layer and a first Cu alloy layer on a substrate and patterning the first metal adhesion layer and the first Cu alloy layer;
sequentially stacking a gate insulating layer, an active layer, and an ohmic contact layer on the gate line and the gate electrode;
forming source and drain electrodes and a data line, the forming source and drain electrodes and a data line including sequentially depositing a second metal adhesion layer and a second Cu alloy layer on the ohmic contact layer and patterning the second metal adhesion layer and the second Cu alloy layer; and
sequentially patterning the active layer and the ohmic contact layer.

28. The method of claim 27, wherein the patterning the second metal adhesion layer and the second Cu alloy layer includes etching the second metal adhesion layer and the second Cu alloy layer with a dry etching process.

29. The method of claim 28, further comprising forming a top metal layer on the second Cu alloy layer.
